(19) United States
(12) Patent Application Publication
(10) Pub. No.: US 2014/0034974 A1
(43) Pub. Date: Feb. 6, 2014

(54) LIGHT-EMITTING DEVICE

(71) Applicant: EPISTAR CORPORATION, Hsinchu City (TW)

(72) Inventor: Hsien Wei LI, Hsinchu City (TW)

(73) Assignee: EPISTAR CORPORATION, Hsinchu City (TW)

(21) Appl. No.: 13/955,556

(22) Filed: Jul. 31, 2013

(30) Foreign Application Priority Data
Jul. 31, 2012 (TW) 101127689

(51) Int. Cl. H01L 33/08

(52) U.S. Cl. CPC H01L 33/08
USPC 257/88

(57) ABSTRACT

A light-emitting diode device is disclosed, which includes a substrate; a plurality of light-emitting diode units, each of the light-emitting diode units being an equilateral polygon with more than four sides, are disposed on the substrate; wherein each of the light-emitting diode units includes a first electrical connecting area disposed along a first side of the light-emitting diode unit, a second electrical connecting area disposed along a second side of the light-emitting diode unit, and a conductive connecting structure disposed on each of the electrical connecting areas; wherein each of the electrical connecting area electrically connects to one another light-emitting diode unit through the conductive connecting structure.

### TECHNICAL FIELD

The application relates to a light-emitting diode device, and more particularly, to a light-emitting diode device emitting light uniformly and having a high reliability. The light-emitting diode device comprises the structure with a plurality of light-emitting diode units formed on a single substrate.

### REFERENCE TO RELATED APPLICATION

This application claims the right of priority based on TW application Serial No. 101127689, filed on Jul. 31, 2012, and the content of which is hereby incorporated by reference in its entirety.

### DESCRIPTION OF BACKGROUND ART

The lighting theory and structure of light-emitting diode (LED) is different from that of conventional lighting source. An LED has advantages like low power loss, long life-time, no need for warming time, and fast responsive time. Moreover, it is small, shockproof, and suitable for mass production so LEDs are widely adopted in the market. For example, LEDs can be used in optical display apparatus, laser diodes, traffic lights, data storage devices, communication devices, illumination devices, medical devices, and so on.

The conventional light-emitting diode device 1 shown in FIGS. 1A and 1B comprises a substrate 10, a plurality of light-emitting diode units 12 closely arranged on the substrate 10. Every light-emitting diode unit 12 comprises one p-type semiconductor layer 121, one light-emitting layer 122, one n-type semiconductor layer 123, one first electrical connecting area 16, and one second electrical connecting area 18. The electrical connecting areas (16, 18) indicate the areas used to electrically connect the adjacent light-emitting diode units 12. By forming a conductive connecting structure 19 on the electrical connecting areas of two adjacent light-emitting diode units 12, the two adjacent light-emitting diode units 12 can be electrically connected to each other. Because the substrate 10 is electrically insulating, after forming the grooves 14 by etching between the light-emitting diode units 12, each light-emitting diode unit 12 can be insulated to each other. Then, etching part of each light-emitting diode unit 12 to the n-type semiconductor layer 123 and forming a conductive connecting structure 19 on the first electrical connecting area 16 of the n-type semiconductor layer 123 and the second electrical connecting area 18 of the p-type semiconductor layer 121, respectively; furthermore, the first electrical connecting areas 16 and the second electrical connecting areas 18 of the plurality of the light-emitting diode units 12 are selectively connected by the conductive connecting structures 19 in order to make the plurality of the light-emitting diode units 12 to be electrically connected in parallel or in series. Wherein, electrodes can also be formed respectively on the electrical connecting areas (16, 18) to reduce the contact resistance between the surfaces of the semiconductor layers and the conductive connecting structure 19. It can be the air under the conductive connecting structure 19, or an insulating layer 13 can be formed on partial surfaces of the semiconductor layers of the light-emitting diode units 12 and the regions between the adjacent light-emitting diode units 12 by chemical vapor deposition method (CVD), physical vapor deposition method (PVD), or sputtering method and so on in order to protect and electrically insulate the semiconductor layers of the adjacent light-emitting diode units 12 before forming the conductive connecting structure 19. The material of the insulating layer 13 can be aluminum oxide (Al₂O₃), silicon dioxide (SiO₂), aluminum nitride (AlN), silicon nitride (SiNₓ), titanium oxide (TiO₂), or the combination thereof.

Besides, a first electrode pad 16′ and a second electrode pad 18′ can be formed on the n-type semiconductor layer 123 and p-type semiconductor layer 121 of the two light-emitting diode units 12 located at the ends of the light-emitting diode device 1, respectively. The electrode pads (16′, 18′) can be electrically connected to the external power source by wiring or by soldering as shown in FIG. 1B.

However, when the light-emitting diode units 12 are electrically connected by the conductive connecting structure 19, because the height difference between the grooves 14 and the light-emitting units 12 is large, the conductive connecting structures 19 formed to connect the light-emitting diode units 12 breaks easily to cause the connecting failure and to influence the yield of the device.

Besides, when connecting to the rectangular light-emitting diode units 12, because the connecting circuit has to be designed based on the shape of the substrate 10, the electrical connecting areas (16, 18) relative to the light-emitting units 12 can't be fixed and often have to be located at the corners of the light-emitting diode units. In this kind of design, the distances between the electrical connecting areas of the light-emitting diode units 12 are different (as the distances d and d′ shown in FIG. 1B), the voltage drops between the light-emitting diode units 12 are different, and therefore the light emitting brightness between the light emitting diode units 12 varies easily. When we form the electrical connecting areas (16, 18) in the corners, because the corners are right angles, it is difficult for the current to spread and the light emitting efficiency also degrades easily.

Besides, the aforementioned light emitting diode device 1 can be further connected to other devices to constitute a light-emitting apparatus 100. FIG. 2 illustrates a conventional light-emitting apparatus 100. As shown in FIG. 2, a light-emitting apparatus 100 comprises one submount 110 having one electrical circuit 101 thereon; the aforementioned light-emitting diode device 1 attached on the submount 110; and an electrical connecting structure 104 electrically connecting the first electrode pad 16′ and the second electrode pad 18′ of the first light-emitting diode device 1 and the electrical circuit 101 on the submount 110. Wherein, the aforementioned submount 110 can be a lead frame or a large-sized mounting substrate which is advantageous to circuit design of the light-emitting apparatus and heat dissipating. The aforementioned electrical connecting structure 104 can be a bonding wire or other connecting structures.

### SUMMARY OF THE APPLICATION

The application relates to a light-emitting diode device, and more particularly, to a light-emitting diode device emitting light uniformly and having a high reliability. Wherein the light-emitting diode device comprises the structure with a plurality of light-emitting diode units formed on a single substrate.

A light-emitting diode device is disclosed, which includes a substrate; a plurality of light-emitting diode units, each of the light-emitting diode units being an equilateral polygon with more than four sides, are disposed on the substrate; wherein each of the light-emitting diode units includes a first electrical connecting area disposed along a first side of the light-emitting diode unit, a second electrical connecting area disposed along a second side of the light-emitting diode unit, and a conductive connecting structure disposed on each of the electrical connecting areas; wherein each of the electrical connecting area electrically connects to one another light-emitting diode unit through the conductive connecting structure.

A light-emitting diode device is disclosed, which includes a substrate; a first light-emitting diode unit and a second light-emitting diode unit which are equilateral polygons with more than four sides disposed on the substrate; wherein each of the first light-emitting diode unit and the second light-emitting diode unit includes a first electrical connecting area disposed along a first side of the first light-emitting diode unit, a second electrical connecting area disposed along a second side of the second light-emitting diode unit, and a conductive connecting structure electrically connecting the first electrical connecting area of the first light-emitting diode unit and the second electrical connecting area of the second first light-emitting diode unit.

### BRIEF DESCRIPTION OF THE DRAWINGS

FIG. 1A illustrates a side-viewed diagram of a conventional light-emitting diode device;

FIG. 1B illustrates a top-viewed diagram of a conventional light-emitting diode device;

FIG. 2 illustrates a side-viewed diagram of a conventional light-emitting apparatus;

FIG. 3A illustrates a top-viewed diagram of a light-emitting diode device in accordance with a first embodiment of the present application;

FIG. 3B illustrates a side-viewed diagram of a light-emitting diode device in accordance with a first embodiment of the present application;

FIGS. 4A-4B illustrate the top-viewed diagrams of the light-emitting diode devices in accordance with another embodiment of the present application;

FIGS. 5A-5C illustrate the circuit diagrams of the light-emitting diode devices in accordance with another embodiment of the present application;

FIGS. 6A-6C illustrate the top-viewed diagrams of the light-emitting diode devices in accordance with further another embodiment of the present application;

FIGS. 7A-7C illustrate the circuit diagrams of the light-emitting diode devices in accordance with further another embodiment of the present application;

FIGS. 8A-8C illustrate the top-viewed diagrams of the light-emitting diode devices in accordance with another embodiment of the present application.

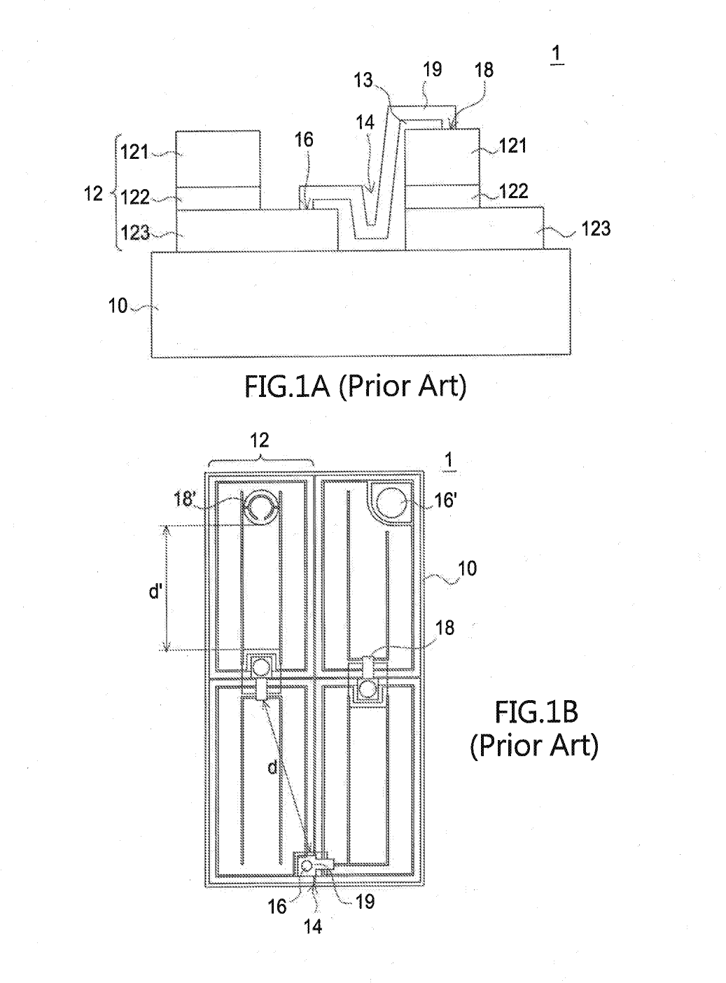

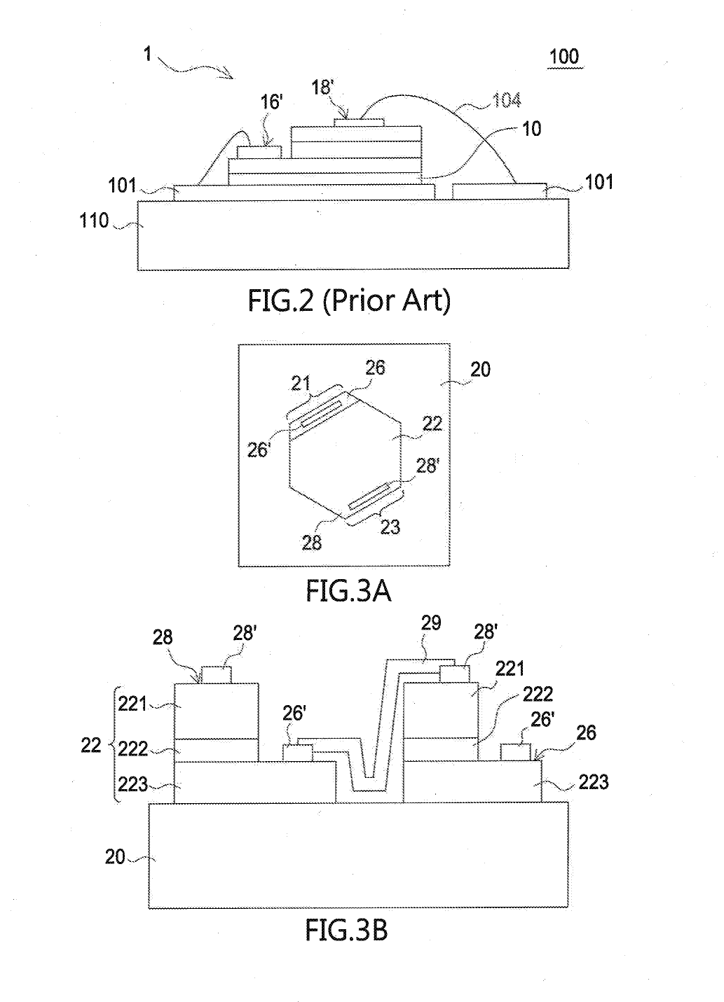

### DETAILED DESCRIPTION OF PREFERRED EMBODIMENTS

The embodiment of the application is illustrated in detail, and is plotted in the drawings. The same or the similar part is illustrated in the drawings and the specification with the same number.

FIGS. 3A and 3B illustrate the structures of a light-emitting diode unit 22 in accordance with an embodiment of the present application. The light-emitting diode unit 22 is an equilateral hexagon formed on the substrate 20. The light-emitting diode unit 22 includes a first type semiconductor layer 223, for example, an n-type semiconductor layer; a light-emitting layer 222; a second type semiconductor layer 221, for example, a p-type semiconductor layer; a first electrical connecting area 26; and a second electrical connecting area 28. Wherein, the n-type semiconductor layer 223 of the light-emitting diode unit 22 includes a first electrical connecting area 26 disposed along a first side and the p-type semiconductor layer 221 of the light-emitting diode unit 22 includes a second electrical connecting area 28 disposed along a second side 23. In order to reduce the probability of the short circuit when being electrically connected to other light-emitting diode units 22, the first side 21 which exposes the surface of the first type semiconductor layer and the second side 23 which has the surface of the second type semiconductor layer are not adjacent to each other. Similarly, the first electrode 26′ and the second electrode 28′ can also be formed respectively on the electrical connecting areas (26, 28) to lower the contact resistance between the surface of the semiconductor layers and the conductive connecting structure when a plurality of light-emitting diode units 22 are electrically connected to one another through the conductive connecting structures.

When the shapes of the light-emitting diode units 22 are equilateral hexagonal and the electrical connecting areas (26, 28) are formed along the sides of the light-emitting units 22, the light-emitting diode units 22 are rotational symmetric.

Therefore, when the light-emitting diodes 22 are formed on the substrate being electrically connected in series or in parallel with one another, the light-emitting diode units 22 can be electrically connected to one another through the electrical connecting areas (26, 28) located at the sides of the light-emitting diode units 22 by the conductive connecting structures (not shown) in order to form a closely arranged light-emitting diode device.

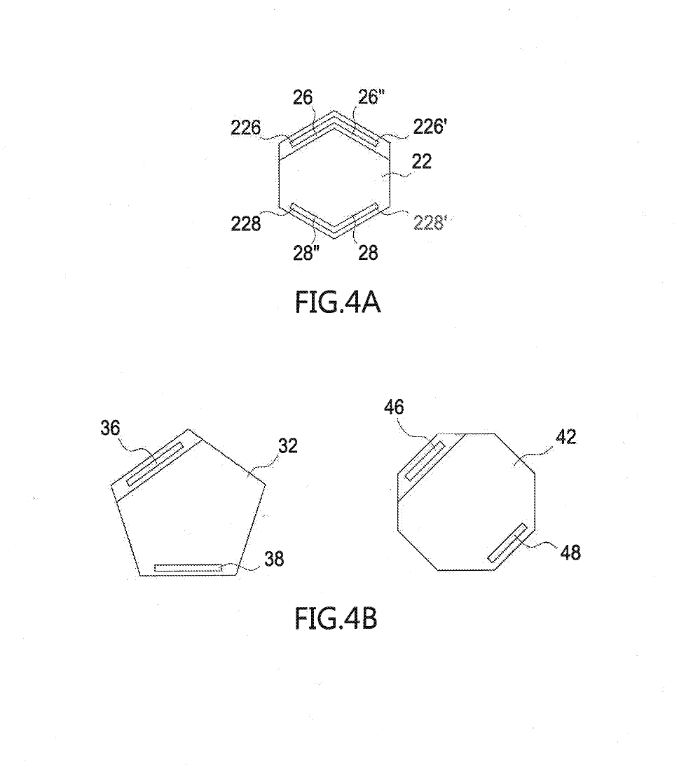

Developing from this embodiment, in coordination with the circuit design for the light-emitting diode units 22, a first electrical connecting area and a third electrical connecting area (26, 26″) with the same polarity can be located along two adjacent sides on a semiconductor layer by, for example, exposing the n-type semiconductor layer to form a platform along the adjacent first side and third side of the hexagonal shape by photolithography technology to provide a first electrical connecting area 26 and a third electrical connecting area 26″. Then, a first electrode 226 and a third electrode 226′ can be respectively formed on the electrical connecting areas 26 and 26″ at the first side and the third side, a second electrical connecting area 28 and a fourth electrical connecting area 28″ can be formed at the adjacent second side and fourth side, and then a second electrode 228 and a fourth electrode 228′ can further be selectively formed on the second electrical connecting area 28 and the fourth electrical connecting area 28″, as shown in FIG. 4A.

Therefore, the design can make more light-emitting diode units 22 electrically connecting to one another in different directions more easily. The person with ordinary skill in the art can realize that under different circuit design, the numbers of the electrical connecting areas can be adjusted and are not limited to two or four.

Under the same spirit of the present application, the shape of the light-emitting diode units as other equilateral polygons with more than four sides as shown in FIG. 4B can be further illustrated. For example, the shape of the light-emitting diode unit 32 is equilateral pentagon and the shape of the light-emitting diode unit 42 is equilateral octagon. Besides, the first electrical connecting areas (36, 46) and the second electrical connecting areas (38, 48) can also be arranged along the adjacent or the non-adjacent sides of the light-emitting diode units. Comparing with the conventional rectangular light-emitting diode unit, because the included angle of each light-emitting diode unit (larger than 90°), the problem the current crowded at the corner of the light-emitting diode unit and spreading uneasily can be solved and the light emitting uniformity can be increased.

Besides, the person with ordinary skill in the art can realize that under different design, a plurality of light-emitting diode units with different shapes such as equilateral pentagons, equilateral hexagons, or equilateral octagons can be combined by being adjacent to one another side by side, and electrically connected to one another through the electrical connecting areas located at the sides of the light-emitting diode units by the conductive connecting structures in order to form variety of different light-emitting diode devices.

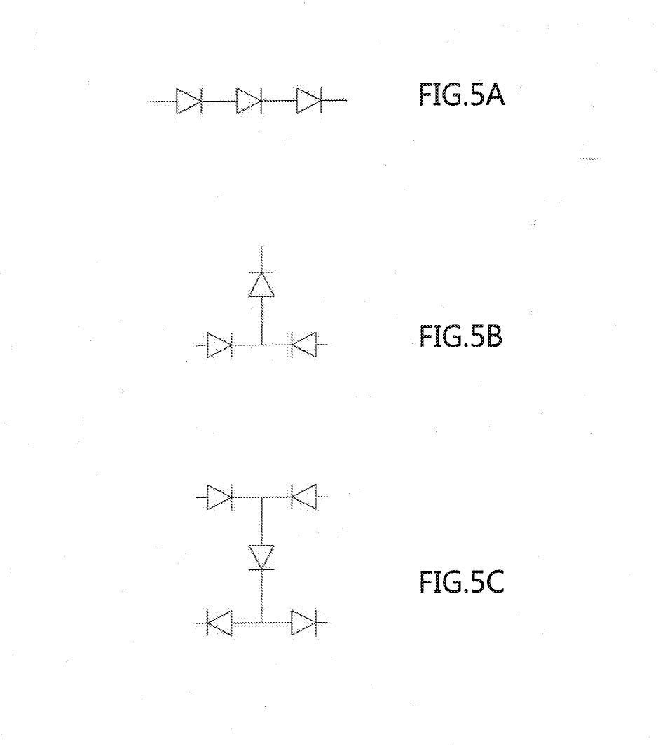

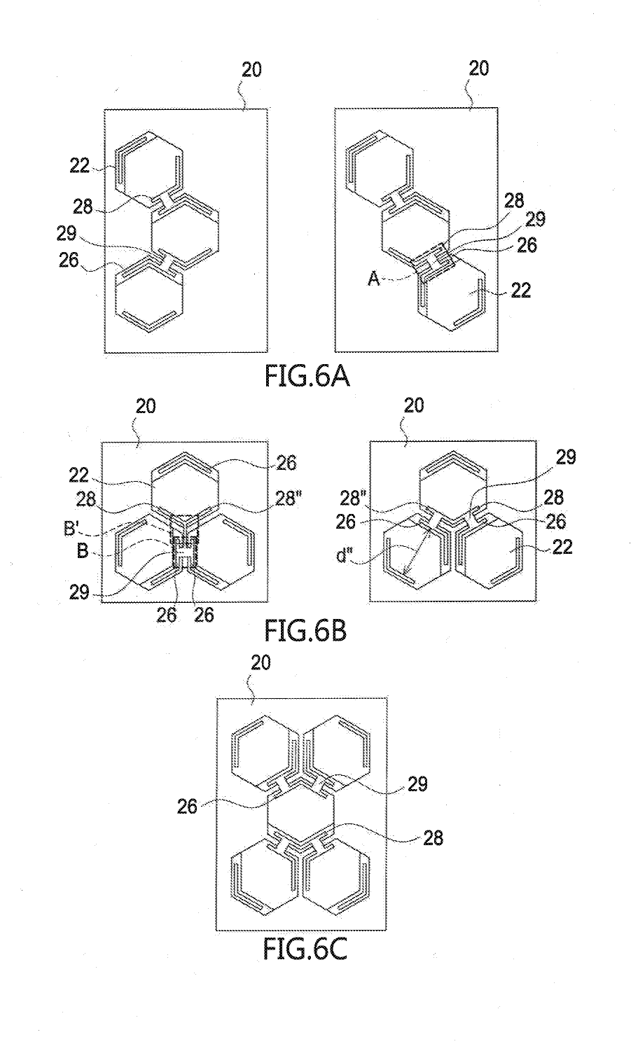

Then, referring to FIGS. 5A, 5B, and 5C, the circuit diagrams with a plurality of light-emitting diode units 22 serially connected in a straight line, connected together with three terminals, and connected with another four light-emitting diodes 22 formed on a single substrate 20 are disclosed, and FIGS. 6A, 6B, and 6C disclose the possible arrangements corresponding to FIGS. 5A, 5B, and 5C, respectively. Wherein, the plurality light-emitting diode units 22 are arranged on the substrate 20 adjacent to one another. Corresponding to the circuit design, the first electrical connecting areas 26 and the second electrical connecting areas 28 of different light-emitting diode units 22 are arranged adjacent to one another side by side.

Then, according to the need of circuit connection, a conductive connecting structure 29 is arranged on the corresponding electrical connecting areas (26, 28). Through the conductive connecting structure 29, the first electrical connecting area 26 of one light-emitting diode unit 22 can be electrically serially connected to the second electrical connecting area 28 of another adjacent light-emitting diode unit 22 (as the dotted line area A shown in FIG. 6A), or the second electrical connecting area 28 of one light-emitting diode unit 22 can be electrically parallel connected to the second electrical connecting area 28 of another adjacent light-emitting diode unit 22 (as the dotted line area B shown in FIG. 6B).

It is worth noticing that besides of the way of connecting between the light-emitting diode units 22 shown here, which is electrically connected with one another through the conductive connecting structure side by side, the left diagram and the right diagram in FIG. 6B discloses different connecting methods, respectively.

In the left diagram of FIG. 6B, for the light-emitting diode unit 22 at the upper part to electrically connect to the lower two adjacent light-emitting units 22 together with three terminals, the joining part of the second electrical connecting area 28 and the fourth electrical connecting area 28″ at the bottom of the upper part light-emitting diode unit 22 can be electrically connected to the first electrical connecting areas 26 of the lower two light-emitting diode units 22 through the conductive connecting structure 29 terminal by terminal (as the dotted line area B′ shown in FIG. 6B), wherein the conductive connecting structure 29 connects to the first electrical connecting areas 26 of the two lower light-emitting diode units 22 in the same time. In the right diagram of FIG. 6B, the second electrical connecting area 28 and the fourth electrical connecting area 28″ located at two upper sides of the light-emitting diode unit 22 electrically connect to the first electrical connecting areas located at the upper sides of the two lower adjacent light-emitting units 22 respectively through the conductive connecting structure 29 side by side. These designs not only can fix the relative positions of the electrical connecting areas (26, 28) on the light-emitting diode unit 22 but also can fix the distances between the electrical connecting areas (26, 28). The distance between the first electrical connecting area 26 and the second electrical connecting area 28 is about the distance between the opposite sides of the equilateral hexagonal light-emitting, diode unit 22 (as the distance d″ shown in FIG. 6B). The device can therefore emit light more uniformly and the reliability thereof can therefore be raised.

Wherein, the substrate 20 in the light-emitting diode device can be single material substrate or be a composite. For example, the substrate 20 can include two connecting first substrate and second substrate (not shown). In the present embodiment, the material of the substrate 20 is Sapphire. However, the material of the substrate 20 can also include, but not be limited to, lithium aluminum oxide (LiAlO₂), zinc oxide (ZnO), gallium nitride (GaP), glass, organic polymer, or aluminum nitride (AlN). Then, a plurality of light-emitting diode units 22 as disclosed in the embodiments of the present application are formed on a surface of the substrate 20. In the present embodiment, the illustrated manufacturing method is disclosed as the following:

Referring to FIG. 3B, it discloses the side-viewed diagram of a light-emitting diode unit 22,

At first, forming an n-type semiconductor layer 223, a light-emitting layer 222, and a p-type semiconductor layer 221 on a growth substrate (not shown), and in the present embodiment, the material of the growth substrate is GaAs. Of course, besides of GaAs, the material of the growth substrate can include but not be limited to germanium (Ge), indium phosphide (InP), sapphire, silicon carbide (SiC), silicon (Si), lithium aluminum oxide (LiAlO₂), zinc oxide (ZnO), gallium nitride (GaN), or aluminum nitride (AlN).

Then, after selectively etching part of the semiconductor layers by the photolithographic technology, the remained part of the semiconductor layers on the growth substrate forms a plurality of semiconductor layer structures adjacent by side to form the equilateral hexagonal light-emitting diode units 22. In order to enhance the light-emitting efficiency of the device, the light-emitting diode units 22 can be arranged on a transparent substrate 20 by the substrate transferring technology and the substrate bonding technology. The light-emitting diode units 22 can be connected to the transparent substrate 20 by heating or adding pressure directly or through a transparent adhesive layer (not shown). Wherein, the transparent adhesive layer can be an organic polymeric glue, for example, the material of the transparent adhesive layer can be PI, BCB, PFCB, Epoxy, Acrylic Resin, PET, PC, or the combination thereof; the transparent adhesive layer can be a transparent conductive metal layer, for example, the material of the transparent adhesive layer can be ITO, InO, SnO, FTO, ATO, CTO, AZO, GZO, or the combination thereof; or the transparent adhesive layer can be an inorganic insulating layer, for example, the material of the transparent adhesive layer can be aluminum oxide (Al₂O₃), silicon dioxide (SiO₂), aluminum nitride (AlN), silicon nitride (SiNₓ), titanium oxide (TiO₂), or the combination thereof.

Then, forming the n-type exposed semiconductor region(s) along the side(s) of each light-emitting diode unit 22 to be the platform for forming the electrical connecting area or electrode.

In the present embodiment, the light-emitting diode units are connected to the transparent substrate 20 by using the organic polymer BCB to be the transparent adhesive layer. Actually, the method to arrange the light-emitting diode units 22 on the transparent substrate 20 is not limited to the present embodiment. People with ordinary skill in the art can realize, according to different structure properties, the light-emitting diode unit 22 can also be formed directly on the transparent substrate. Besides, according to different number of times of the substrate transferring, the structure with p-type semiconductor layer adjacent to the substrate, n-type semiconductor layer on the p-type semiconductor, and a light-emitting layer in-between can also be formed.

Then, forming an insulating layer (not shown) on part of surfaces of the semiconductor layers of the light-emitting diode units 22 and the regions between the adjacent light-emitting diode units 22 by chemical vapor deposition method (CVD), physical vapor deposition method (PVD), or sputtering method and so on in order to protect and electrically insulate the semiconductor layers of the adjacent light-emitting diode units 22. The material of the insulating layer can be aluminum oxide (Al₂O₃), silicon dioxide (SiO₂), aluminum nitride (AlN), silicon nitride (SiNₓ), titanium oxide (TiO₂), or the combination thereof.

Then, by sputtering, forming a first electrode 26′ on the first electrical connecting area 26 which is on the surface of the n-type exposed semiconductor region of the light-emitting diode unit 22, forming a second electrode 28′ on the second electrical connecting area 28 which is on the surface of the p-type semiconductor layer of the light-emitting diode 22, and forming a conductive connecting structure 29 on the surface of the transparent substrate 20 in order to form the electric connection between the light-emitting diode units. Taking the present embodiment for example, forming a first electrode 26′ on the first electrical connecting area 26 which is on the surface of the n-type exposed semiconductor region of the first light-emitting diode unit 22, forming a second electrode 28′ on the second electrical connecting area 28 which is on the surface of the p-type semiconductor layer 223 of the adjacent light-emitting diode 22, and forming a conductive connecting structure 29 between the two electrodes (26′, 28′) to electrically connect serially two adjacent light-emitting diode units.

The material of the conductive connecting structure 29 and the electrodes (26′, 28′) are preferred to be metal, for example, Au, Ag, Cu, Cr, Al, Pt, Ni, Ti, Sn, the alloy thereof, or the stack thereof. The material of forming the first electrode 26′, the second electrode 28′, and the conductive connecting structure 29 can be the same or different. However, the first electrode 26′ and second electrode 28′ can also be omitted. In other words, two adjacent light-emitting diode units 22 can be electrically connected by a single conductive connecting structure 29 directly connecting to the electrical connecting areas (26, 28) of two adjacent light-emitting diode units 22. The structure can be formed by a single step or by several steps.

Similarly, the material between the conductive connecting structure 29 and the transparent substrate 20 can be air, or an insulating layer can be formed on part of surfaces of the semiconductor layers of the light-emitting diode units 22 and the regions between the adjacent light-emitting diode units 22 by chemical vapor deposition method (CVD), physical vapor deposition method (PVD), or sputtering method and so on in order to protect and electrically insulate the semiconductor layers of the adjacent light-emitting diode units 22 before forming the conductive connecting structure 29. The material of the insulating layer can be aluminum oxide (Al₂O₃), silicon dioxide (SiO₂), aluminum nitride (AlN), silicon nitride (SiNₓ), titanium oxide (TiO₂), or the combination thereof.

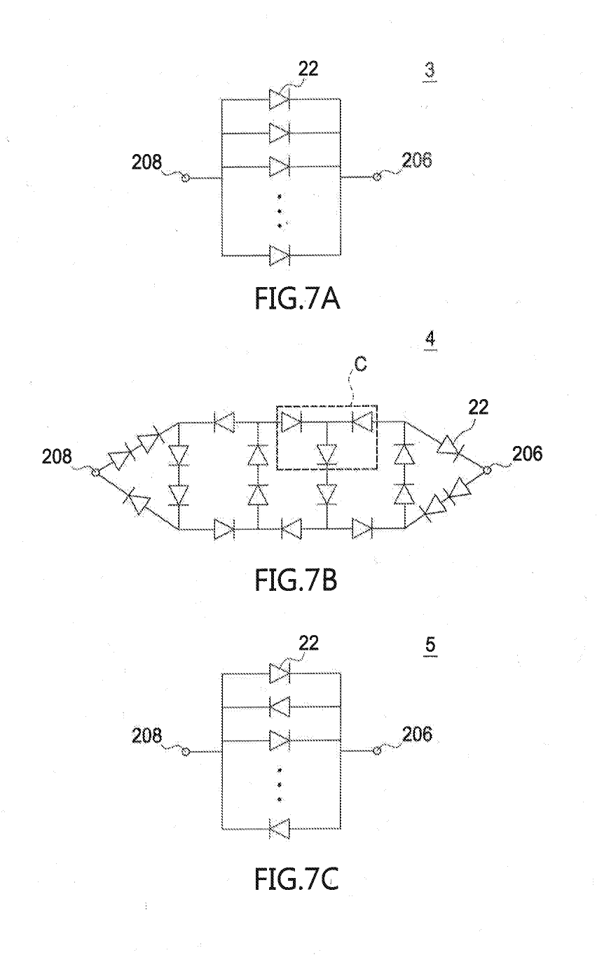

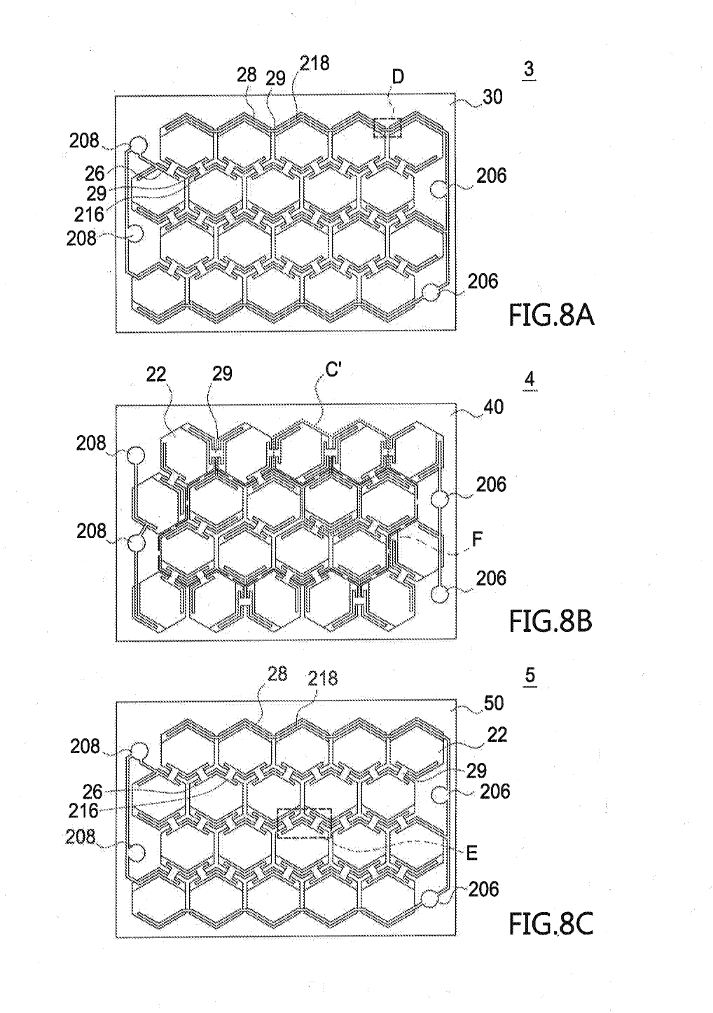

Then, referring to FIGS. 7A, 7B, and 7C, which disclose the circuit diagrams of light-emitting diode devices 3, 4, and 5, respectively, and FIGS. 8A, 8B, and 8C disclose the possible arrangements corresponding to FIGS. 7A, 7B, and 7C, respectively.

FIG. 7A discloses a circuit diagram of a light-emitting diode device 3 with a plurality of light-emitting diode units electrically connected to one another in parallel. Then, referring to the arrangement of FIG. 8A, in the top line of the light-emitting diode units 22, at the upper end of each light-emitting diode unit 22, the second electrical connecting area 28 and the fourth electrical connecting area 218 are electrically in parallel connected to one another through the conductive connecting structure 29; similarly, at the lower end of each light-emitting diode unit 22, the first electrical connecting area 26 and the third electrical connecting area 216 are electrically connected to one another in parallel through the conductive connecting structure 29. Besides, the first electrical connecting area 26 and the third electrical connecting area 216 arranged along two adjacent sides at the lower end of each light-emitting diode unit 22 in the first line further electrically connect the first electrical connecting areas 26 and the third electrical connecting areas 216 arranged at the upper end of two corresponding different light-emitting diode units 22 in the second line through the conductive connecting structure 29. It is worth noticing that the connecting method, besides connecting side by side as disclosed here, the upper ends of the adjacent light-emitting units 22 in the first line and the lower ends of the adjacent light-emitting diode units 22 in the lowest line can also be electrically connected to one another terminal by terminal through the conductive connecting structure 29, as the dotted area D shown in FIG. 8A.

The rest may be deduced by analogy. FIG. 8A constitutes a light-emitting diode device 3 with twenty light-emitting diode units 22 electrically connected with one another in parallel on a single substrate 30.

In order to reduce the influence the opaque metal electrode pad on the light-emitting efficiency of the light-emitting diode device 3, in the present embodiment, the ends of the conductive connecting structure 29 extend to the surfaces of the substrate 30 outside of the hexagonal light-emitting diode semiconductor layers to form two first electrode pads 206 and two second electrode pads 208, respectively. Through the four electrode pads (206, 208), the light-emitting diode device 3 can electrically connect to external power by wiring or by bonding. Wherein, the method of forming the electrode pads (206, 208) can be combined with the method of forming the conductive connecting structure 29 in a single step or can be formed in many steps. The material of forming the electrode pads 206, 208 can be the same as or different from the material of forming the conductive connecting structure 29.

People with ordinary skill in the art can realize, under different device structure design, the number of the electrode pads can be adjusted and is not limited to four. Besides, with different concern, such as the difficulty of the manufacturing method, the first electrode pad and the second electrode pad can also be formed on the surface of the semiconductor layer and are not limited to be formed on the surface of the substrate.

FIG. 7B discloses another circuit diagram of a bridge-rectifying light-emitting diode device 4 with a plurality of light-emitting diode units electrically connected to one another in parallel and in series. Referring to the corresponding arrangement of FIG. 8B, the electrical connecting areas of the light-emitting diode units 22 are electrically connected side by side as need. Besides, the region connected together with three terminals (as the dotted area C shown in FIG. 7B) in the bridge-rectifying light-emitting diode device 4 are connected as disclosed in the left diagram of FIG. 6B through the conductive connecting structure 29, and the structure thereof is shown as the dotted line area C′ in FIG. 8B.

The rest may be deduced by analogy. FIG. 8B constitutes a bridge-rectifying light-emitting diode device 4 with twenty light-emitting diode units 22 electrically connected with one another in parallel and in series on a single substrate 40. When the alternative current inputs through the first electrode pad 206 and the second electrode pad 208 into the bridge-rectifying light-emitting diode device 4, under the positive voltage, half of the light-emitting diode units in the bridge-rectifying light-emitting diode device 4 emit light; under the negative voltage, the other half of the light-emitting diode units in the bridge-rectifying light-emitting diode device 4 emit light. Wherein, because of the circuit design, some of the light-emitting diode units in the bridge-rectifying light-emitting diode device 4 emit light under both the positive voltage and the negative voltage. As the bridge-rectifying light-emitting diode device 4 disclosed in the present embodiment, eight light-emitting diode units 22 emit light under both positive voltage and negative voltage as the dotted line area F shown in FIG. 8B.

People with ordinary skill in the art can realize under different circuit and device structure design, the number of the light-emitting diode units emits light under the positive voltage and the negative voltage can be adjusted and is not limited to eight.

FIG. 7C discloses another circuit diagram of a light-emitting diode device 5 with a plurality of light-emitting diode units electrically connected to one another in anti-parallel. Referring to the corresponding arrangement of FIG. 8C, in the top line of the light-emitting diode units 22, at the upper end of each light-emitting diode unit 22, the second electrical connecting area 28 and the fourth electrical connecting area 218 are electrically connected to one another in parallel through the conductive connecting structure 29; similarly, at the lower end of each light-emitting diode unit 22, the first electrical connecting area 26 and the third electrical connecting area 216 are electrically connected in parallel to one another through the conductive connecting structure 29. Besides, the first electrical connecting area 26 and the third electrical connecting area 216 arranged along two adjacent sides at the lower end of each light-emitting diode unit 22 in the first line further electrically connect the first electrical connecting areas 26 and the third electrical connecting areas 216 arranged at the upper end of two corresponding different light-emitting diode units 22 in the second line through the conductive connecting structure 29. It is worth noticing that in order to form the anti-parallel connecting structure here, the first electrical connecting area 26 and the third electrical connecting area 216 at the lower sides of each light-emitting diode unit 22 in the second line are electrical serially connected to the second electrical connecting area 28 and the fourth electrical connecting area 218 at the upper sides of each light-emitting diode unit 22 in the third line through the conductive connecting structure 29 as the dotted line area E shown in FIG. 8C.

The rest may be deduced by analogy. FIG. 8C constitutes an alternative current light-emitting diode device 5 with twenty light-emitting diode units 22 electrically parallel and serially connected with one another on a single substrate 50. When the alternative current inputs through the first electrode pad 206 and the second electrode pad 208 into the alternative current light-emitting diode device 5, under the positive voltage, half of the light-emitting diode units in the alternative current light-emitting diode device 5 emit light; when under the negative voltage, the other half of the light-emitting diode units in the alternative current light-emitting diode device 5 emit light. As the alternative current light-emitting diode device 5 disclosed in the present embodiment, twenty light-emitting diode units 22 (ten groups) emit light alternatively under positive voltage and negative voltage.

In the content of the present application, the equilateral hexagonal light-emitting diode unit is used to replace the conventional rectangular light-emitting diode unit, and the electrical connecting areas are arranged on four corresponding sides of the hexagonal light-emitting diode. Taking advantage of the rotational symmetric feature of the light-emitting diode unit, when electrically connecting the light-emitting diode units, we can only rotate the light-emitting diode units and no need to change the positions of the electrical connecting areas on the light-emitting diode units. Therefore, the structure with one point connected together with three terminals and the structure one single light-emitting diode unit connected with four other light-emitting diode units can be achieved more easily. When electrically connecting the light-emitting diode units, because the relative positions between the electrical connecting areas are fixed, the device can emit light more uniformly and the reliability thereof can be raised.

Besides, because the electrical connecting areas are arranged along the sides of the light-emitting diode units, the electrical connecting areas which are need to be electrically connected can neighbor on each other and be connected side by side. Electrically connected the electrical connecting areas through the conductive connecting structure can reduce the disadvantage resulted from the conventional electrical connecting areas arranged at the corners of the light-emitting diode unit, smaller corner angles, the current are crowded at the corners and are not spread easily in the conventional light-emitting diode unit. Because the equilateral polygonal light-emitting diode units with more than four sides having larger corner angle, it has the effect to reduce the current crowded at the corners.

The principle and the efficiency of the present application illustrated by the embodiments above are not the limitation of the application. Any person having ordinary skill in the art can modify or change the aforementioned embodiments. Therefore, the protection range of the rights in the application will be listed as the following claims.

What is claimed is:

1. A light-emitting diode device, comprising:
a substrate;
a plurality of light-emitting diode units, wherein each of the light-emitting diode units is an equilateral polygon with more than four sides disposed on the substrate, comprising:
a first electrical connecting area disposed along a first side of the light-emitting diode unit; and
a second electrical connecting area disposed along a second side of the light-emitting diode unit; and
a conductive connecting structure disposed on each of the electrical connecting areas;
wherein each of the electrical connecting areas electrically connects to at least one another light-emitting diode unit through the conductive connecting structure.

2. The light-emitting diode device of claim 1, wherein each of the light-emitting diode units further comprises:
a first electrical-type semiconductor layer;
a second electrical-type semiconductor layer disposed on the first electrical-type semiconductor layer; and
a light-emitting layer disposed between the first electrical-type semiconductor layer and the second electrical-type semiconductor layer;
wherein the first electrical connecting area is disposed on the first electrical-type semiconductor layer and the second electrical connecting area is disposed on the second electrical-type semiconductor layer.

3. The light-emitting diode device of claim 1, wherein each of the light-emitting diode units further comprises a third electrical connecting area disposed on a third side of the light-emitting diode unit.

4. The light-emitting diode device of claim 1, wherein the third side is adjacent to the first side.

5. The light-emitting diode device of claim 1, wherein the third electrical connecting area is disposed on the first electrical-type semiconductor layer or on the second electrical-type semiconductor layer.

6. The light-emitting diode device of claim 1, wherein the first side is not adjacent to the second side.

7. The light-emitting diode device of claim 3, wherein each of the light-emitting diode units further comprises a fourth electrical connecting area disposed on a fourth side of the light-emitting diode unit.

8. The light-emitting diode device of claim 7, wherein at least one of the light-emitting diode units electrically connects to other four light-emitting diode units through the conductive connecting structures.

9. The light-emitting diode device of claim 1, wherein the light-emitting diode units form an alternative current light-emitting diode device or a bridge-rectifying light-emitting diode device.

10. The light-emitting diode device of claim 1, wherein the light-emitting diode units are equilateral hexagons, equilateral pentagons, or the combination thereof.

11. A light-emitting diode device, comprising:
a substrate;
a first light-emitting diode unit and a second light-emitting diode unit which are equilateral polygons with more than four sides disposed on the substrate;
wherein each of the first light-emitting diode unit and the second light-emitting diode unit comprises:
a first electrical connecting area disposed along a first side of the first light-emitting diode unit; and
a second electrical connecting area disposed along a second side of the second light-emitting diode unit; and
a conductive connecting structure electrically connecting the first electrical connecting area of the first light-emitting diode unit and the second electrical connecting area of the second first light-emitting diode unit.
